(19) United States
(12) Patent Application Publication
(10) Pub. No.: US 2025/0363265 A1
(43) Pub. Date: Nov. 27, 2025

(54) INFORMATION PROCESSING APPARATUS, INFORMATION PROCESSING METHOD, AND COMPUTER READABLE RECORDING MEDIUM

(71) Applicant: NEC Corporation, Tokyo (JP)

(72) Inventors: Yoshiyuki YAJIMA, Tokyo (JP); Takahiro KUMURA, Tokyo (JP)

(73) Assignee: NEC Corporation, Tokyo (JP)

(21) Appl. No.: 19/210,059

(22) Filed: May 16, 2025

(30) Foreign Application Priority Data
May 24, 2024 (JP) 2024-084805

(51) Int. Cl. G06F 30/20; G08G 1/01

(52) U.S. Cl. CPC G06F 30/20; G08G 1/0125

(57) ABSTRACT

Disclosed is an information processing apparatus including a setting unit for setting parameter sets of a traffic-flow theoretical model to be used in traffic-flow simulation that applies the traffic-flow theoretical model, a simulation unit for running the traffic-flow simulation for each of the parameter sets, and a determining unit for selecting traffic-flow simulation data, similar to traffic-flow measurement data actually measured, from the traffic-flow simulation data as a result of the traffic-flow simulation, and determining a parameter set corresponding to the selected similar traffic-flow simulation data for a parameter set to be used in traffic-flow prediction.

### CROSS REFERENCE TO RELATED APPLICATION

This application is based upon and claims the benefit of priority from Japanese patent application No. 2024-084805, filed on May 24, 2024, the disclosure of which is incorporated herein in its entirety by reference.

### TECHNICAL FIELD

The present disclosure relates to an information processing apparatus and an information processing method for predicting traffic congestion, and a computer readable recording medium.

### BACKGROUND ART

Traffic congestion is currently predicted based on knowledge and experiences of experts. Specifically, experts such as traffic congestion forecasters use trends or patterns of the past traffic congestions to predict how much and where traffic congestion will occur in the future. However, in order to train the experts, it is necessary to gain experiences required for forecasting traffic congestion. Instead, a method with use of traffic-flow simulation has been suggested.

As for a technique related thereto, PLT 1 (JP 2010-067180 A) discloses a traffic condition prediction system that verifies and predicts traffic congestion. According to the traffic condition prediction system in JP 2010-067180 A, current traffic-related data of a target road is first used to calculate a model parameter of each vehicle to be set in traffic-flow simulation that can reproduce the current traffic condition. Then, the traffic condition prediction system in JP 2010-067180 A sets traffic congestion events to the model parameter and required points on the target road, and performs traffic-flow simulation to predict traffic conditions until set time is reached.

Specifically, the traffic condition prediction system in JP 2010-067180 A is disclosed that calculates a mean velocity and number of vehicles from traffic volume, density, and the like, runs the vehicles at the mean velocity for a certain period of time with use of traffic-flow simulation to perform optimization calculation with use of vehicle parameters such as accelerations, and brakes as functions, and then, calculates model parameters (initial value parameters) for the individual vehicles that can reproduce the current traffic condition.

However, the traffic condition prediction system in JP 2010-067180 A fails to clearly disclose a calculation method for the model parameters for the individual vehicles in the traffic-flow simulation. In addition, in JP 2010-067180 A, the traffic-flow simulation is performed under an assumption that all vehicles travel at the measured mean velocity. However, real traffic-flow has differences in velocity among the vehicles and various vehicle behaviors from time to time, and thus is complex. Therefore, the current traffic condition is considered poor in degree of reproduction or accuracy of future prediction, making it impossible to predict traffic congestion with high accuracy.

### SUMMARY

An example object of the invention is to predict traffic-flow using parameter sets of a theoretical model of traffic flow (hereafter, traffic-flow theoretical model) with high accuracy that can reproduce a traffic condition similar to a current traffic condition.

In order to achieve the example object described above, an information processing apparatus according to an example aspect of the present disclosure includes:
a setting unit for setting parameter sets of a traffic-flow theoretical model to be used in traffic-flow simulation that applies the traffic-flow theoretical model,
a simulation unit for running the traffic-flow simulation for each of the parameter sets, and
a determining unit for selecting traffic-flow simulation data, similar to actual traffic-flow measurement data, from the traffic-flow simulation data as a result of the traffic-flow simulation, and determining a parameter set corresponding to the selected similar traffic-flow simulation data for a parameter set to be used in traffic-flow prediction.

Also, in order to achieve the example object described above, an information processing method according to an example aspect of the present disclosure includes:
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to actual traffic-flow measurement data, from the traffic-flow simulation data as a result of the traffic-flow simulation, and
determining a parameter set, corresponding to the selected similar traffic-flow simulation data, for a parameter set to be used in traffic-flow prediction.

Furthermore, in order to achieve the example object described above, a computer-readable recording medium according to an example aspect includes a program recorded on the computer-readable recording medium, the program including instructions that cause the computer to carry out:
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to actual traffic-flow measurement data, from the traffic-flow simulation data as a result of the traffic-flow simulation, and
determining a parameter set, corresponding to the selected similar traffic-flow simulation data, for a parameter set to be used in traffic-flow prediction.

According to the present disclosure as described above, traffic-flow prediction can be performed using the parameter sets of the traffic-flow theoretical model with high accuracy that can reproduce a traffic condition similar to a current traffic condition.

### BRIEF DESCRIPTION OF THE DRAWINGS

FIG. 1 is a diagram for explaining one example of the information processing apparatus;

FIG. 2 illustrates one example of a system provided with the information processing apparatus;

FIG. 3 is a diagram for explaining the cellular automaton;

FIG. 4 is a diagram for explaining the bottleneck;

FIGS. 5A to 5D are a diagram for explaining determination of the traffic-flow parameter set;

FIG. 6 is a diagram for explaining the particle filtering in the case of a single parameter set to be determined (estimated);

FIG. 7 is a diagram for explaining the similarity;

FIGS. 8A to 8B are a diagram for explaining one example of displaying the traffic-flow (mean velocity) measurement data and the posterior probability of each traffic-flow parameter;

FIG. 9 is a diagram for explaining one example of displaying a prediction result and a correct value;

FIG. 10 is a diagram for explaining the operation of the information processing apparatus; and

FIG. 11 is a diagram for explaining one example of a computer that realizes the information processing apparatus in the example embodiment.

### EXAMPLE EMBODIMENT

### Example Embodiment

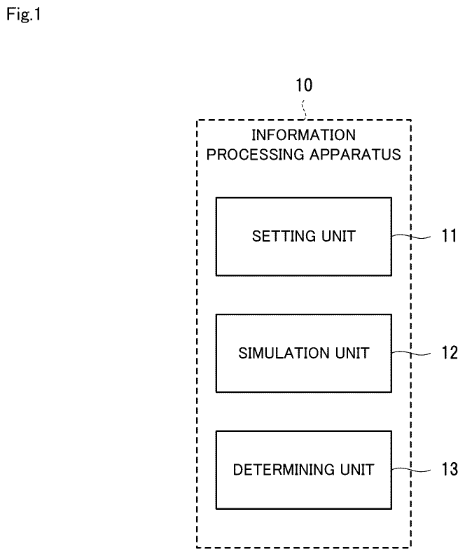

The following describes a configuration of an information processing apparatus in one example embodiment with FIG. 1. FIG. 1 is a diagram for explaining one example of the information processing apparatus.

### Apparatus Configuration

An information processing apparatus 10 shown in FIG. 1 is an apparatus for performing traffic-flow prediction (traffic-flow simulation apparatus) using highly accurate parameters that can reproduce a traffic condition similar to a current traffic condition through data assimilation with a traffic-flow theoretical model proposed in traffic engineering. Moreover, as shown in FIG. 1, the information processing apparatus 10 includes a setting unit (setting means) 11, a simulation unit (simulation means) 12, and a determining unit (determining means) 13.

The setting unit 11 sets parameter sets of a traffic-flow theoretical model to be used in traffic-flow simulation that applies the traffic-flow theoretical model. The simulation unit 12 runs the traffic-flow simulation for each of the parameter sets.

The determining unit 13 selects traffic-flow simulation data, similar to traffic-flow measurement data actually measured, from the traffic-flow simulation data as results of the traffic-flow simulation, and determines a parameter set, corresponding to the selected most similar traffic-flow simulation data, for a parameter set to be used in traffic-flow prediction. The traffic-flow simulation for the prediction is carried out with the determined parameter set in the determining unit 13.

In such a manner as above, since the parameter set of traffic-flow theoretical model with high accuracy can be determined that can reproduce a traffic condition similar to the current traffic condition in this example embodiment, traffic-flow prediction with high accuracy is performable.

### System Configuration

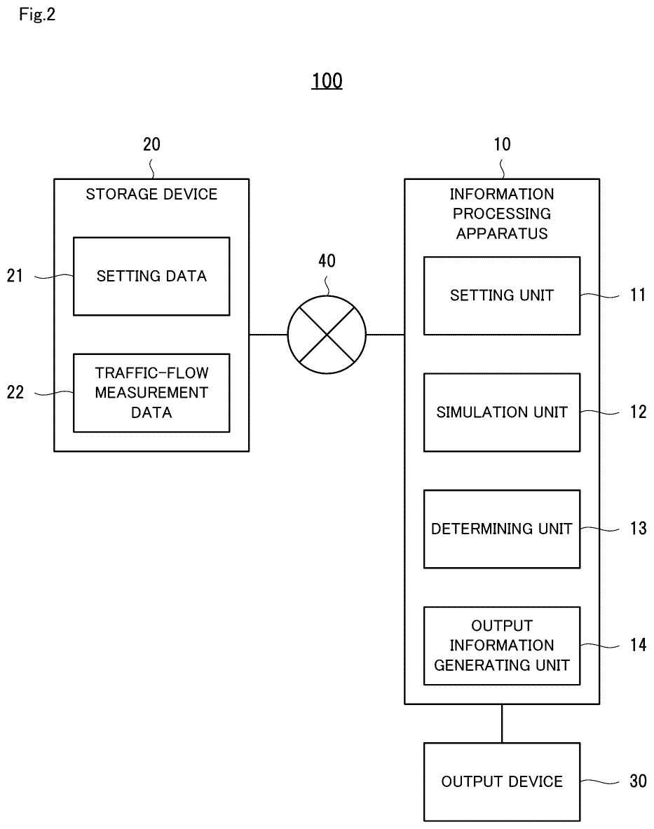

The following describes more specifically a configuration of the information processing apparatus 10 in this example embodiment with FIG. 2. FIG. 2 illustrates one example of a system provided with the information processing apparatus. A system 100 includes the information processing apparatus 10, a storage device 20, an output device 30, and a network 40. The information processing apparatus 10, the storage device 20, and the output device 30 are communicatively connected via the network 40 or the like.

The information processing apparatus 10 is, for example, an information processing apparatus such as a CPU (Central Processing Unit), a programmable device such as an FPGA (Field-Programmable Gate Array), a GPU (Graphics Processing Unit), or a circuit that incorporates one or more of these, a server computer, a personal computer, a mobile terminal, or the like.

In the example of FIG. 2, the simulation unit 12 is installed inside the information processing apparatus 10, but it may be installed outside the information processing apparatus 10. For example, the simulation unit 12 may be installed in a server computer or the like that is provided separately from the information processing apparatus 10.

The storage device 20 is a database, a server computer, a circuit with a memory, and the like. The storage device 20, for example, stores at least setting data and traffic-flow measurement data. Now in the example of FIG. 2, the storage device 20 is installed outside the information processing apparatus 10, but it may be installed inside the information processing apparatus 10.

The output device 30 acquires output information mentioned later, and outputs generated image, sounds, and the like in accordance with the output information. The output device 30 is, for example, an image display device using a liquid crystal, organic EL (Electro Luminescence), or a CRT (Cathode Ray Tube). In addition, the image display device may include an audio output device such as a speaker or the like. Here, the output device 30 may be a printing device such as a printer and the like.

The network 40 is a general network constructed with use of communication lines, such as the Internet, LAN (Local Area Network), leased lines, telephone lines, corporate networks, mobile communication networks, Bluetooth (registered trademark), Wi-Fi (Wireless Fidelity) (registered trademark).

The following describes in detail the information processing apparatus 10.

As shown in FIG. 2, the information processing apparatus 10 in the example embodiment includes the setting unit 11, the simulation unit 12, the determining unit 13, and an output information generating unit 14.

### Regarding Setting Unit

The setting unit 11 first obtains setting data, necessary for the traffic-flow simulation, from setting data 21 stored in the storage device 20. Next, the setting unit 11 sets the obtained setting data in the simulation unit 12.

The setting data contains at least a road parameter set, a traffic-flow parameter set, simulation condition information, and inflow traffic-volume time series information. Note that the setting data is not limited to the road parameter set, the traffic-flow parameter set, the simulation condition information, and the inflow traffic-volume time series information.

The road parameter set is a set of parameters used to build a simulation model (road model) of a target road in traffic-flow simulation applying a traffic-flow theoretical model.

Examples of the traffic-flow theoretical models include the S-NFS (Stochastic Nishinari-Fukui-Schadschneider) model. Specifically, the S-NFS model is a stochastic cellular automata (CA) model that describes behaviors of vehicles individually.

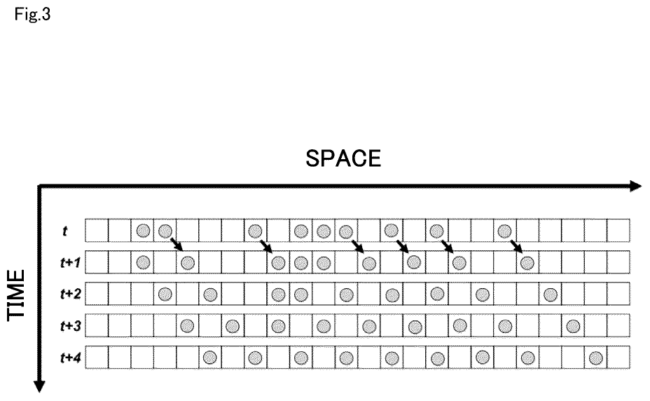

The cellular automaton is to be described. FIG. 3 is a diagram for explaining a cellular automata-based traffic-flow model. In the cellular automata model (CA model), space-time and velocities are represented as discrete values. In the CA model example in FIG. 3, one lane of a road is represented by a row of cells, and a vehicle velocity is represented by how many cells a vehicle (○) will advance (arrows) in the next time step (t, t+1, t+2, t+3, t+4).

Moreover, a space is divided discretely (cells), and numbers “0” or “1” is assigned to the cells individually (binarization). The number “0” indicates that no vehicle is present, and the number “1” indicates that a vehicle is present. In other words, the number “1” is moved along cells. In addition, the vehicle is moved based on a predetermined rule. The rule may be that, for example, if one cell is empty in a direction where the vehicles move, a target vehicle moves to that cell.

For details of the S-NFS model, see Reference Document 1 (Satoshi Sakai, Katsuhiro Nishinari, and Shinji Iida, “A new stochastic cellular automaton model on traffic-flow and its jamming phase transition,” J. Phys. A: Math. Gen. 39 (2006) 15327-15339, [retrieved on May 14, 2024], the Internet <URL: https://iopscience.iop.org/article/10.1088/0305-4470/39/50/002/pdf>).

However, the traffic-flow theoretical model based on CA models is not limited to the S-NFS model, but also include the Nishinari-Fukui-Schadschneider model (Reference 2: Katsuhiro Nishinari, Minoru Fukui, and Andreas Schadschneider, “A Stochastic Cellular Automaton Model for Traffic-flow with Multiple Metastable States,” J. Phys. A: Math. Gen. 37 (2004) 3101-3110, [retrieved on May 21, 2024], the Internet <URL: https://iopscience.iop.org/article/10.1088/0305-4470/37/9/003>), and the Nagel-Schreckenberg model (Reference 3: Kai Nagel & Michael Schreckenberg, “A Cellular Automaton Model for Freeway Traffic,” J. Phys. I France. 2 (1992) 2221-2229, [retrieved on May 21, 2024], the Internet <URL: https://jp1.journaldephysique.org/en/articles/jp1/abs/1992/12/jp1v2p2221/jp1v2p2221.html>). In addition to CA models, the traffic flow theoretical model includes kinematic-wave models such as the Lighthill-Whitham-Richards (LWR) model (Reference 4: Michael James Lighthill and Gerald Beresford Whitham, “On kinematic waves II. A theory of traffic flow on long crowded roads”, Proceedings of the Royal Society of London. Series A. Mathematical and Physical Sciences. 229 (1955) 317-345, [retrieved on May 13, 2025], the Internet <URL: https://royalsocietypublishing.org/doi/10.1098/rspa.1955.0089>, Reference 5: Paul I. Richards, “Shock Waves on the Highway”, Operations Research. 4 (1956) 42-51, [retrieved on May 13, 2025], the Internet <URL: https://pubsonline.informs.org/doi/10.1287/opre.4.1.42>) and the Aw-Rascle-Zhang (ARZ) model (Reference 6: Aw, A. and Michel Rascle, “Resurrection of “Second Order” Models of Traffic Flow” SIAM J. Appl. Math. 60 (2000) 916-938, [retrieved on May 13, 2025], the Internet <URL: https://epubs.siam.org/doi/10.1137/S0036139997332099 >, Reference 7: H. M. Zhang, “A non-equilibrium traffic model devoid of gas-like behavior”, Transportation Research Part B: Methodological, 36 (2002) 275-290, [retrieved on May 13, 2025], the Internet <URL: https://www.sciencedirect.com/science/article/abs/pii/S0191261500000503>), car-following models such as the Newell's car-following model (Reference 8: G. F. Newell, “A simplified car-following theory: a lower order model”, Transportation Research Part B: Methodological, 36 (2002) 195-205, [retrieved on May 13, 2025], the Internet <URL: https://www.sciencedirect.com/science/article/abs/pii/S0191261500000448>), and optimal velocity models (e.g., Reference 9: Yuki Sugiyama, “Optimal Velocity Model for Traffic Flow”, Computer Physics Communications, 121-122 (1999) 399-401, [retrieved on May 13, 2025], the Internet <URL: https://www.sciencedirect.com/science/article/abs/pii/S0010465599003665>).

The traffic-flow parameter set is a set of parameters of the traffic-flow theoretical model to be set when running traffic-flow simulation. Specifically, in the S-NFS model, velocities of vehicles are determined individually based on the following (1) to (5).
(1) Maximum velocity Vmax on a lane of the target road
(2) Velocity updating to avoid the collision to the vehicle ahead: Collision avoidance
(3) Random brake probability p: One-step deceleration (random brake effect)
(4) Slow-to-start probability q: velocity updating based on distance between vehicles at previous step (inertia, time delay in reaction, slow-to-start effect)
(5) Anticipation probability r: Velocity updating using distance to vehicle S vehicles ahead (future anticipation). S=2 for probability r, and S=1 for probability 1−r.

Then, at least parameters as followings are used as the traffic-flow parameter set to be adjusted for reproducing the measured traffic-flow: a maximum velocity VBN within a bottleneck, a random brake probability p, a slow-to-start probability q, and an anticipation probability r to be described next.

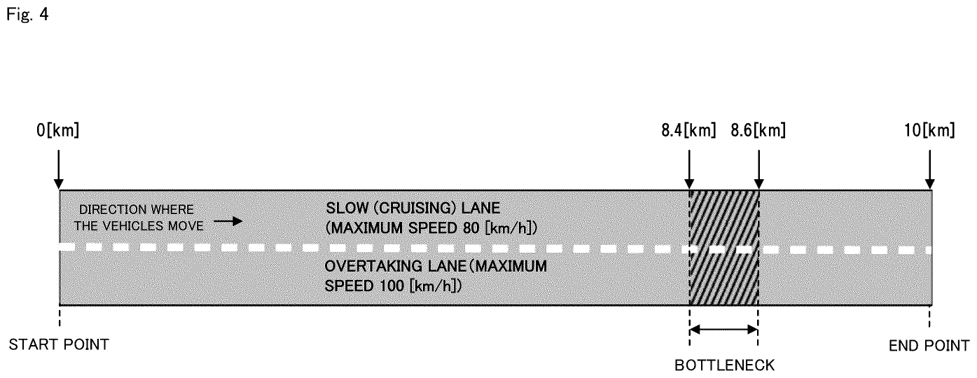

The bottleneck is a section where the vehicle velocity is decreased and traffic congestion occurs, and corresponds to, for example, an uphill, a sag section, a tunnel, and a tollgate. FIG. 4 is a diagram for explaining the bottleneck. In the example of FIG. 4, a section of the target road between 8.4 and 8.6 [km] (kilometers) corresponds to a bottleneck (shaded area). Instead of V_{BN}, one can use different random brake probability p_{BN} in the bottleneck to introduce the bottleneck section in the simulation. Here, p_{BN} must be larger than the random brake probability outside the bottleneck.

As an example (parameter set example), it is considered that the traffic-flow parameter set consists of one cell: 10 [m] (meter), time step size: 1.8 [second], velocity resolution: 20 [km/h] (kilometer per hour) (derived as follows; 10 [m]/1.8 [second]=50/9 [m/sec]), maximum velocity V_{BN} within the bottleneck being 20, 40, or 60 [km/h] (3 patterns), random brake probability p being in a range of 0.05 to 0.6 in 0.05 increments (12 patterns), slow-to-start probability q being in a range of 0.1 to 0.8 in 0.1 increments (8 patterns), and anticipation probability r being in a range of 0.75 to 0.99 in 0.03 increments (9 patterns). In the case of the setup described above, the traffic-flow parameter set has 2592 patterns (=3×12×8×9). However, the sampling of the traffic-flow parameter sets is not limited to the above-described setups like grid search.

The simulation condition information is information representing the simulation condition used in the traffic-flow simulation. For example, simulation end time and initial conditions are contained.

The inflow traffic-volume time series information is information representing inflow traffic volume on the target road in time-series. The inflow traffic-volume time series information is, for example, acquired by measuring the number of vehicles per unit time (time-series data) flowing into a start point of the target road (at 0 [km]) by a traffic counter.

### Regarding Simulation Unit

The simulation unit 12 runs the traffic-flow simulation for plurality of different traffic-flow parameter sets in a set period of time. The set period of time is a predetermined period of time past current time, such as 10 to 60 [minutes] past before the current time. However, it is not limited to the period of time described above. In the example of the traffic-flow parameter set described above, the simulation unit 12 runs the maximum of 2592-times traffic-flow simulations.

The simulation unit 12 also performs the traffic-flow simulation for a predetermined period of time after the current time to predict traffic-flow with use of the traffic-flow parameter set to be used in the traffic-flow prediction determined in a determining unit 13, which is mentioned later.

### Regarding Determining Unit

The determining unit 13 calculates a posterior probability distribution, a maximum a posteriori, or an expectation of the posterior probability distribution, or all of them for each parameter set, in accordance with similarity between the traffic-flow measurement data and running results of the traffic-flow simulation (traffic-flow simulation data) performed for each of the different traffic-flow parameter sets during the set period of time, and, based on one or more of these, determines the traffic-flow parameter set to be used in the traffic-flow prediction.

The traffic-flow measurement data is, for example, data actually measured, such as a mean velocity of vehicles, the number of vehicles passing per unit time (flow rate). Also, the traffic-flow measurement data is data measured by sensors installed along the roads such as traffic counters, including optical fiber sensing, a surveillance camera, loop coils, and an ultrasonic sensor, and onboard sensors such as probe vehicle information.

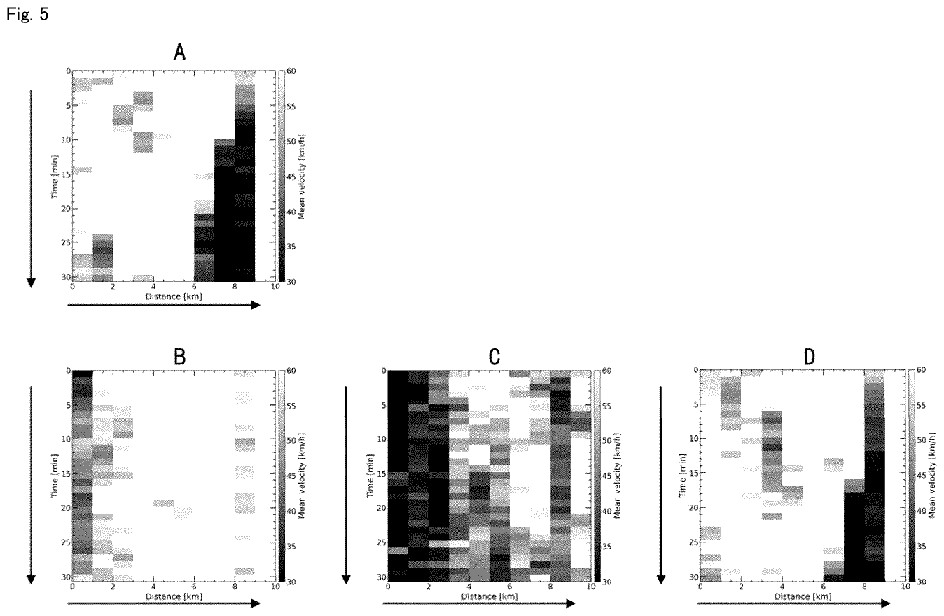

FIG. 5 is a diagram for explaining determination of the traffic-flow parameter set. Numeral A in FIG. 5 represents a change in mean velocity based on the traffic-flow measurement data. Numerals B, C, and D in FIG. 5 each represent a change in mean velocity based on the traffic-flow simulation data. For each of A to D in FIG. 5, a vertical axis represents time, and a horizontal axis represents a direction of the traffic-flow and its distance from the start point. The mean velocity of the vehicles is also represented by color coding from 30 to 60 [km/h]. That is, the mean velocities of the vehicle per 1 [km] section during 1 [minute] are presented in the past 30 [minutes].

Moreover, B in FIG. 5 illustrates the traffic-flow parameter set obtained with probability (p, q, r)=(0.10, 0.8, 0.75). C in FIG. 5 illustrates the traffic-flow parameter set obtained with probability (p, q, r)=(0.55, 0.6, 0.84). D in FIG. 5 illustrates the traffic-flow parameter set obtained with probability (p, q, r)=(0.35, 0.2, 0.99).

In the example in FIG. 5, the traffic-flow parameter set (0.35, 0.2, 0.99) in D of FIG. 5 is determined to be optimal since similarity of mean velocity at each time and location is the highest between A in FIG. 5 and D in FIG. 5. As above, the traffic-flow simulation data with a low absolute percentage error, i.e., similar to the mean velocity based on the traffic-flow measurement data is selected.

The absolute percentage error of the mean velocity is used as the similarity. For example, in the case where an absolute percentage error of up to 10 [%] (percent) is acceptable, and, if the mean velocity in the traffic-flow measurement data is 100 [km/h], an error of up to ±10 [km/h] is acceptable for the mean velocity in the traffic-flow simulation data. In contrast, if the mean velocity in the traffic-flow measurement data is 30 [km/h], only an error of ±3 [km/h] is acceptable for the mean velocity in the traffic-flow simulation data. From this, the absolute percentage error of the mean velocity is considered suitable as an index of the similarity (consistency) of the traffic congestion (low-velocity events). In other words, in order to focus on low velocity events, the absolute percentage error of the mean velocity is used to impose a larger penalty on inconsistency in a low velocity area than in a high velocity area. In addition to the absolute percentage error of mean velocity, an absolute percentage error of an mean flow-rate or an mean density, or the absolute error of mean velocity, mean flow-rate, or mean density may be used as the similarity, or a combination of these may be used.

The following describes in detail a method of determining (estimating) traffic-flow parameter set.

One possible method for determining (estimating) the traffic-flow parameter set is, for example, a processing with use of a particle filter. Specifically, the determining unit 13 determines (estimates) the traffic-flow parameter set based on a particle frequency distribution by performing particle filtering with use of the similarity between the traffic-flow measurement data and the traffic-flow simulation data.

The particle filtering is performed to each traffic-flow simulation data obtained from each different traffic-flow parameter set, at each time t (multiple times t₁ to t_{N}, where N is a positive integer larger than or equal to 2) in the set period of time.

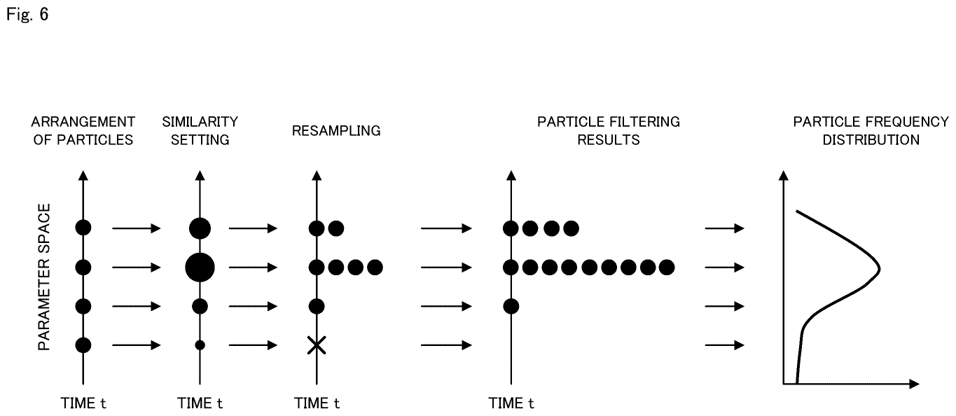

FIG. 6 is a diagram for explaining the particle filtering in the case of a single parameter set to be determined (estimated). In the particle filtering, particles for the traffic-flow parameter set are first (at t=t₀) placed at sampled locations in a parameter space, as shown in FIG. 6.

For example, in the example of the parameter set described above, the parameter space is a four-dimensional real number space that is a set of four parameter sets, i.e., a maximum velocity V_{BN} within the bottleneck, a random brake probability p, a slow-to-start probability q, and an anticipation probability r. From the four-dimensional space, specific values are extracted within a specified range at specified intervals for each parameter like the grid search, as in the example of the parameter set described above.

In the example of the parameter set described above, 2593 parameter sets are sampled by grid search, so 2593 sets of parameters are extracted from the four-dimensional real number space described above. Particles in the particle filter are placed at specific locations in the four-dimensional real number space with values corresponding to parameters sampled from the four-dimensional real number space, e.g., (V_{BN}, p, q, r)=(20, 0.05, 0.1, 0.75).

Next, the similarity between the traffic-flow measurement data and the traffic-flow simulation data is set to the particles of the traffic-flow parameter set at the target time t, as shown in FIG. 6. Now, higher similarity (weight) is set for particles with traffic-flow parameter sets which reproduce similar traffic-flow simulation data. In the example of FIG. 6, the higher the similarity is, more largely a filled circle is represented.

Next, in the particle filtering, resampling is performed in accordance with the weight of the particles, while maintaining the total number of particles. That is, the number of particles to be placed is increased at a location in the parameter space where the particle with large weight is present. In contrast, the number of particles to be placed is decreased at a location where the particle with a smaller weight is present. As a result, more particles are placed in the traffic-flow parameter set that have high similarity to the traffic-flow measurement data (i.e., traffic-flow measurement data is satisfactorily reproducible), and particles with low similarity eventually disappear.

When the particle filtering is completed for times t₀ to t_{N} of the traffic-flow simulation data, many particles are placed in the traffic-flow parameter set with high similarity to the traffic-flow measurement data, as shown in a result of the particle filtering in FIG. 6.

Then, the determining unit 13 calculates statistical information (posterior probability distribution, maximum a posteriori, or expectation of posterior probability distribution, or all of them) for each traffic-flow parameter set based on the frequency distribution of particles in the traffic-flow parameter set that represents similarity, as shown in FIG. 6. In the example of the parameter set described above, the particle filtering results in a simultaneous distribution in the four-dimensional real number space as the parameter space. The simultaneous distribution values are higher for a set of a model parameter with high reproductivity of the measured traffic-flow. The posterior probability distribution of each traffic-flow parameter is obtained by determining a marginal distribution in each of the traffic-flow parameters from the simultaneous distribution, and thus statistical information is obtained.

Then, the determining unit 13 compares the statistical information (posterior probability distribution, maximum a posteriori, or expectation of posterior probability distribution, or one or more from all of them) calculated for each traffic-flow parameter set, and determines (estimates) the traffic-flow parameter set corresponding to the most similar traffic-flow parameter set in accordance with the comparison result for use for traffic-flow prediction. For example, a value at which the posterior probability becomes highest is determined (estimated) as an optimal value of the traffic-flow parameter having the most similarity. Values other than the value at which the posterior probability becomes highest include an expectation of the posterior probability distribution.

The following describes calculation of the similarity.

The determining unit 13 first obtains running results of the traffic-flow simulation (traffic-flow simulation data) that are run for each of the different traffic-flow parameter sets during the set period of time. Moreover, the determining unit 13 obtains traffic-flow measurement data for the set period of time from the traffic-flow measurement data 22 in the storage device 20.

Next, the determining unit 13 calculates the mean velocity of the vehicles at each time point and each section in accordance with the traffic-flow measurement data for the set period of time and the mean velocity of the vehicles at each time point and each section in accordance with traffic-flow simulation data for the set period of time.

Next, the determining unit 13 calculates an absolute percentage error between the mean velocity based on the traffic-flow measurement data and the mean velocity based on the traffic-flow simulation data at each time and in each section.

Next, the determining unit 13 calculates similarity in accordance with the absolute percentage error of the mean velocity of the vehicles at each time point and each section.

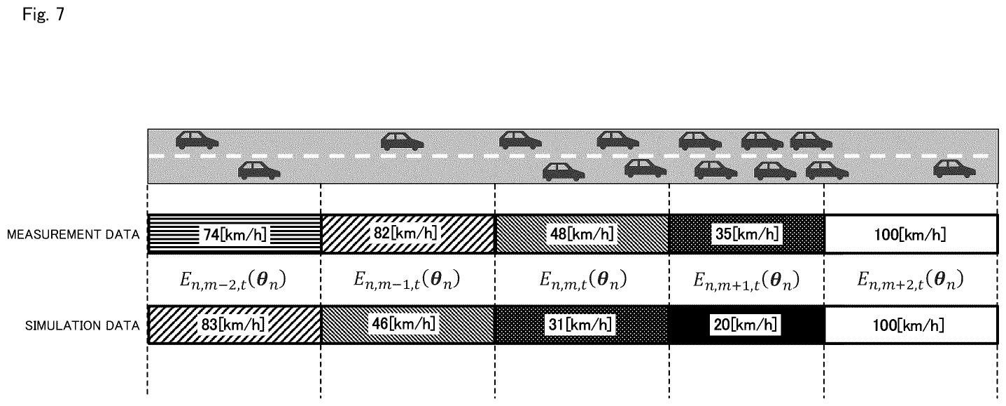

FIG. 7 is a diagram for explaining the similarity. The example in FIG. 7 shows the mean velocities in a plurality of sections individually at time t for the traffic-flow measurement data and the traffic-flow simulation data.

The index of road sections is represented by m (m: a positive integer greater than or equal to 1) sections set on the target road. The mean velocity represents a mean velocity of the m-th section at time t. For example, the mean velocity may be a mean velocity every 1 [minute] in the m-th section at time t.

The absolute percentage error can be expressed as in Equation 1. Note that the n-th (n: 1 to N (the number of all traffic-flow parameter sets)) traffic-flow parameter set is denoted by θn.

$${E}_{n , m , t} ( {θ}_{n} ) = 100 \vert {v}_{n , m , t}^{sim} ( {θ}_{n} ) - {v}_{m , t}^{obs} \vert / {v}_{m , t}^{obs} \qquad [ Equation l ]$$

E_{n,m,t}(θₙ): Similarity

$${v}_{m , t}^{obs} :$$

Mean velocity based on traffic-flow simulation data

$${v}_{n , m , t}^{sim} ( {θ}_{n} ) :$$

Mean velocity based on simulation data

Similarity can be expressed by likelihood, as shown in Equation 2. The total product of each section is calculated in Equation 2 because the likelihood does not decrease in the sum if the absolute percentage error is low in any one of the sections. The hyperparameter σ in Equation 2 may be, for example, 20 to 30 [%]. However, the value of the hyperparameter σ is not limited to 20 to 30 [%].

$${L}_{n , t} ( {θ}_{n} ) ≡ {\prod }_{m} exp - {E}_{n , m , t}^{2} ( {θ}_{n} ) / 2 {σ}^{2} ] / \sqrt{2 {πσ}^{2}} \qquad [ Equation 2 ]$$

σ: Hyperparameter

Here in Equation 2, the similarity decreases unless the similarity (consistence) is high in all the sections where the traffic congestion (low velocity event) occurs. If there is no match in at least one section where the traffic congestion occurs, the similarity decreases.

Since the weight in the particle filtering is to be treated as a positive real number, Equation 2 is converted as shown in Equation 3 (inverse square of logarithmic likelihood is performed).

$${w}_{n , t} ( {θ}_{n} ) ≡ {[ ln {ℒ}_{n , t} ( {θ}_{n} ) ]}^{- 2} \qquad [ Equation 3 ]$$

w_{n,t}(θₙ): Weight

Moreover, the weight is normalized and expressed as in Equation 4. A high weight is set for the similar traffic-flow parameter set, including the location where the low velocity event occurs. By normalizing the weights, the frequency distribution of the weights can be treated as a posterior probability distribution. Therefore, the optimum value of the traffic-flow parameter can be determined from the frequency distribution of the weights as described above. Traffic-flow prediction result is obtained from the simulation adopting the optimal value of the traffic-flow parameter.

$${w}_{n , t} ← \frac{{w}_{n , t}}{{\sum }_{n = 1}^{N} {w}_{n , t}} \qquad [ Equation 4 ]$$

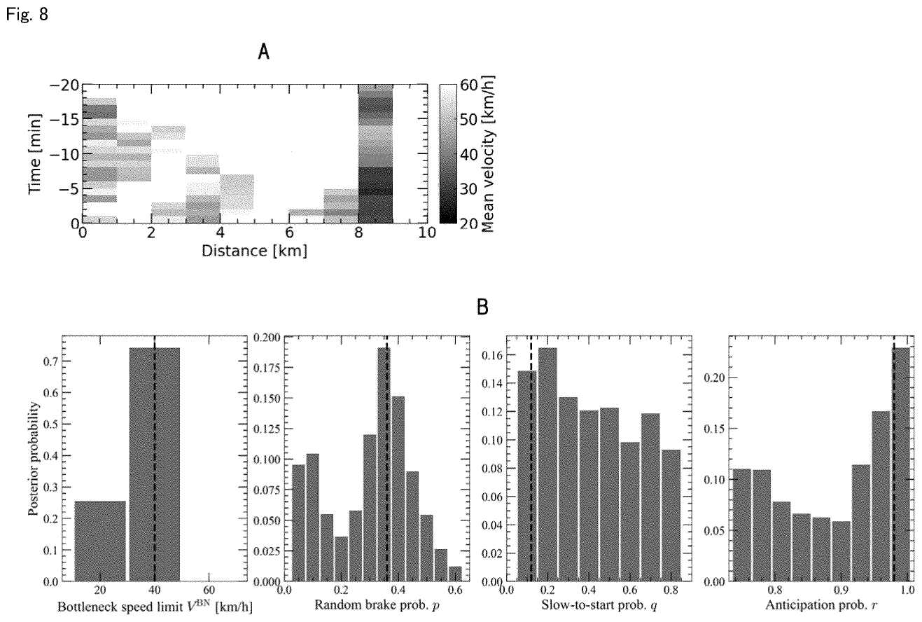

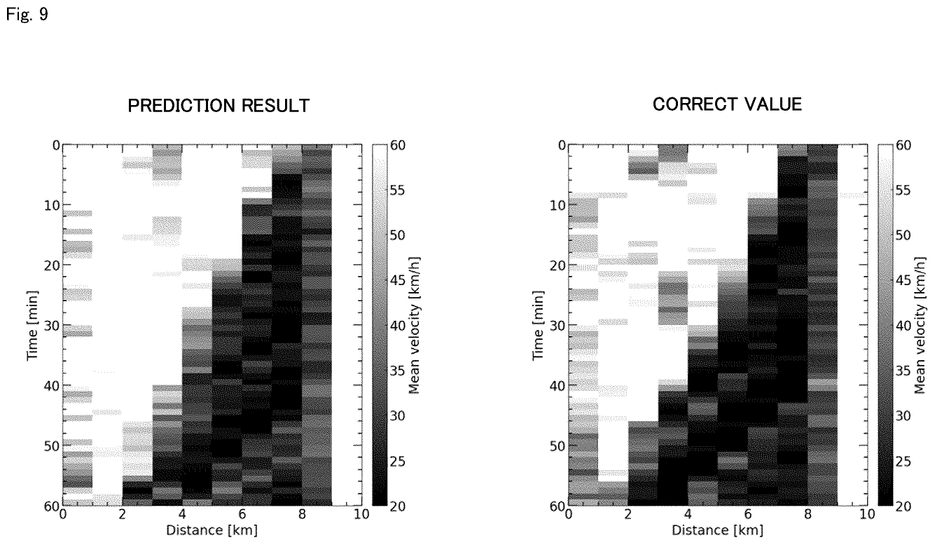

The output information generating unit 14 generates output information for outputting to the output device 30 such as the road model shown in FIG. 4, the traffic-flow (mean velocity) measurement data in the set period shown in A of FIG. 8, the posterior probability (frequency distribution of particles) of each traffic-flow parameter from the result of the particle filtering, the statistical information thereof (posterior probability distribution, maximum a posteriori, or expectation of posterior probability, or one or more from all of them) in B of FIG. 8, the traffic-flow simulation data of the traffic-flow prediction shown in the prediction result of FIG. 9, and the traffic-flow prediction accuracy. Then, the output device 30 obtains the output information output from the output information generating unit 14, and outputs the output information to the output device 30 in accordance with the output information. Here, the traffic-flow simulation data for the similarity and the set period of time may be outputted.

FIG. 8 is a diagram for explaining one example of displaying the traffic-flow (mean velocity) measurement data and the posterior probability of each traffic-flow parameter. FIG. 9 is a diagram for explaining one example of displaying a prediction result and a correct value.

FIG. 8 shows in A thereof a mean velocity as traffic-flow data when the traffic-flow model parameters are (V_{BN}, p, q, r)=(40, 0.36, 0.12, 0.98). In addition, FIG. 8 shows in B the maximum velocity within the bottleneck, the random brake probability, the slow-to-start probability, and the anticipation probability in the traffic-flow model parameters described above.

The dotted lines in B of FIG. 8 represent correct values of the traffic-flow model parameters described above. In the example of FIG. 8, it can be confirmed that the value with the maximum a posteriori is close to the correct value. Moreover, the prediction result of FIG. 9 is obtained by applying the values of the traffic-flow model parameters with the maximum a posteriori and predicting a future mean velocity up to 60 minutes ahead.

The information indicating the traffic-flow prediction accuracy is, for example, information indicating a relationship between a predicted value of the mean velocity and an actual measured value of the mean velocity (a result of regression analysis, a correlation coefficient, a mean absolute error (MAE), a mean squared error (MSE), a root mean squared error (RMSE), a mean percentage error (MPE), or the like. For example, the prediction accuracy for the correct value of the prediction result shown in FIG. 9 contains a correlation coefficient of 0.91, a mean absolute error of 7.0 [km/h], a root mean squared error of 9.8 [km/h], and a mean absolute percentage error of 18 [%].

### Apparatus Operations

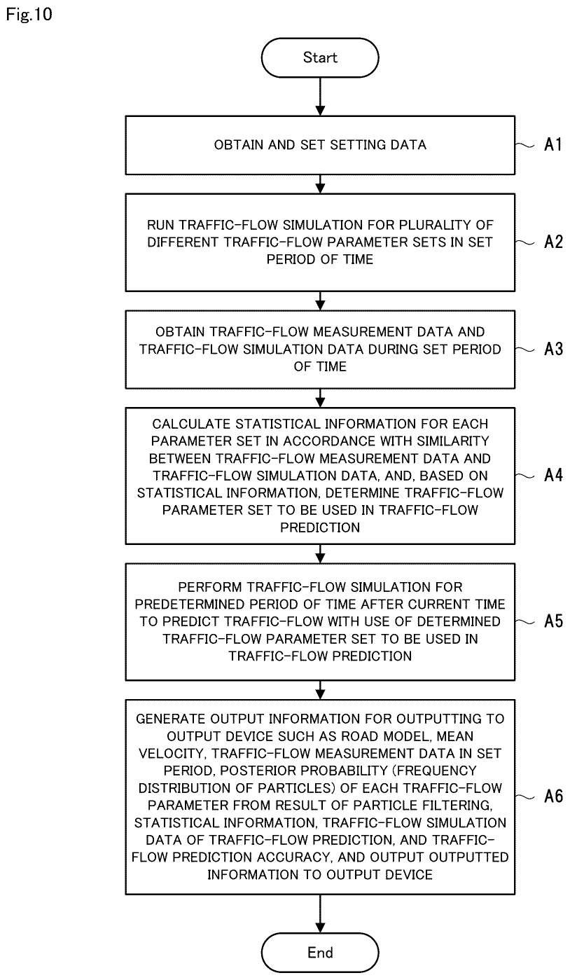

The following describes operation of the information processing apparatus according to the example embodiment with reference to FIG. 10. FIG. 10 is a diagram for explaining the operation of the information processing apparatus. In the following description, the drawings are referred to as appropriate. Moreover, in the example embodiment, an information processing method is implemented by operating the information processing apparatus. Therefore, description of the information processing method in the example embodiment is replaced with the following description of the operation of the information processing apparatus.

As shown in FIG. 10, the setting unit 11 first obtains setting data, necessary for the traffic-flow simulation, from setting data 21 stored in the storage device 20, and sets the obtained setting data in the simulation unit 12 (step A1).

Next, the simulation unit 12 runs the traffic-flow simulation for plurality of different traffic-flow parameter sets in a set period of time (step A2).

Next, the determining unit 13 obtains traffic-flow measurement data and running results of the traffic-flow simulation (traffic-flow simulation data) that are run for each of the different traffic-flow parameter sets during the set period of time (step A3).

Next, the determining unit 13 calculates statistical information (a posterior probability distribution, a maximum a posteriori, or an expectation of the posterior probability distribution, or all of them for each parameter set) in the set period of time in accordance with the similarity between the traffic-flow measurement data and the traffic-flow simulation data, and, based on one or more of the statistical information, determines (estimates) the traffic-flow parameter set to be used in the traffic-flow prediction (step A4).

Specifically, in the step A4, the determining unit 13 determines (estimates) the traffic-flow parameter set based on a particle frequency distribution by performing particle filtering with use of the similarity between the traffic-flow measurement data and the traffic-flow simulation data.

Next, the simulation unit 12 performs the traffic-flow simulation for a predetermined period of time after the current time to predict traffic-flow with use of the traffic-flow parameter set to be used in the traffic-flow prediction determined in the determining unit 13 (step A5).

Next, the output information generating unit 14 generates output information for outputting to the output device 30 such as the road model shown in FIG. 4, the traffic-flow (mean velocity) measurement data in the set period shown in A of FIG. 8, the posterior probability (frequency distribution of particles) of each traffic-flow parameter from the result of the particle filtering, the statistical information thereof (posterior probability, maximum a posteriori, or expectation of posterior probability, or one or more from all of them) in B of FIG. 8, the traffic-flow simulation data of the traffic-flow prediction shown in the prediction result of FIG. 9, and the traffic-flow prediction accuracy, and outputs the outputted information to the output device 30 (step A6). Here, the traffic-flow simulation data for the similarity and the set period of time may be outputted.

Then, the output device 30 obtains the output information output from the output information generating unit 14, and outputs the output information to the output device 30 in accordance with the output information.

### Effects of Example Embodiment

According to the example embodiment as described above, since the parameter set of the traffic-flow theoretical model with high accuracy can be determined that can reproduce a traffic condition similar to a current traffic condition, traffic-flow prediction with high accuracy can be performed.

In addition, in order to train an expert for congestion prediction, a great deal of time for accumulating experience necessary for traffic congestion prediction is required conventionally. However, according to the example embodiment, even a person not an expert can perform traffic-flow prediction (traffic congestion prediction).

Further, in the present situation, automatic search is made to determine whether the tendency and patterns of past data match or not, and traffic-flow prediction (traffic congestion prediction) is performed based on the result of the automatic search. Therefore, a large amount of past data is required as training data. Moreover, it is difficult to cope with a rare or unexpected event (e.g., accident or traffic congestion rapidly developing). According to the example embodiment, since the traffic-flow simulation is performed with use of the traffic-flow parameter sets capable of reproducing the latest road situation, even when a rare or unexpected event occurs, the traffic-flow prediction (traffic congestion prediction) can be performed with high accuracy.

Further, according to the example embodiment, since the traffic congestion can be predicted in advance and the traffic congestion can be suppressed by traffic control, it is possible to reduce a large economic loss of the traffic congestion caused by traffic concentration, an increase in accident risk, and burden on the environment by exhaust gas.

Further, according to the example embodiment, the particle filtering as one method of time-series data assimilation is used, achieving traffic-flow prediction with high accuracy in real time.

As such, since the traffic-flow prediction is performable that can cope with saved data and rare or unexpected events in real-time, the results of the traffic-flow simulation can be combined (data assimilation).

Now, the technique of the present example embodiment can be applied to traffic congestion suppression and traffic accident risk management (enhanced management effect of road operation companies) by patrol car and dynamic road pricing.

Further, the technique is effective in reducing economic loss, environmental load, stress on drivers, and improving services. Further, the technique plays an important role in traffic control and automated vehicle control during a period when automated vehicles are mixed in.

### Program

The program according to the example embodiment may be a program that causes a computer to execute steps A1 to A6 shown in FIG. 10. By installing this program in a computer and executing the program, the information processing apparatus and the information processing method according to the example embodiment can be realized. Further, the processor of the computer performs processing to function as the setting unit 11, the simulation unit 12, the determining unit 13, and the output information generating unit 14.

Also, the program according to the example embodiment may be executed by a computer system constructed by a plurality of computers. In this case, for example, each computer may function as any of the setting unit 11, the simulation unit 12, the determining unit 13, and the output information generating unit 14.

### Physical Configuration

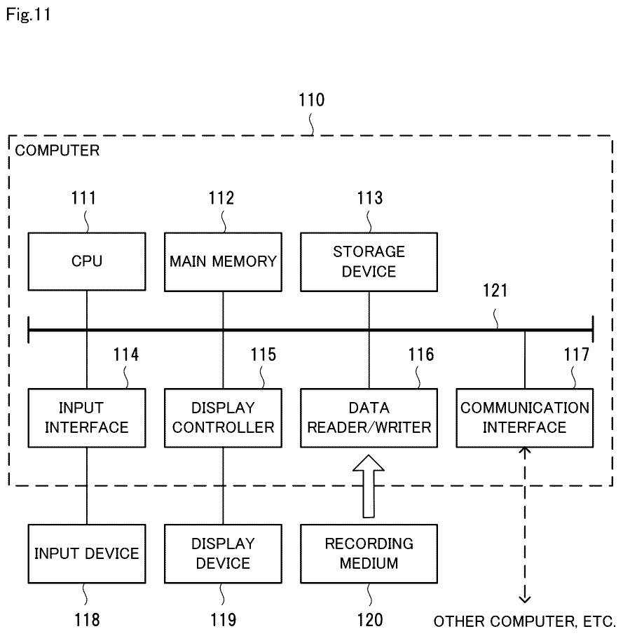

Here, a computer that realizes an information processing apparatus by executing the program according to the example embodiment will be described with reference to FIG. 11. FIG. 11 is a diagram for describing an example of a computer that realizes the information processing apparatus in the example embodiment.

As shown in FIG. 11, a computer 110 includes a CPU 111, a main memory 112, a storage device 113, an input interface 114, a display controller 115, a data reader/writer 116, and a communication interface 117. These units are connected via bus 121 so as to be able to perform data communication with each other. Note that the computer 110 may include a GPU or a FPGA in addition to the CPU 111 or instead of the CPU 111.

The CPU 111 loads a program (codes) according to the example embodiments stored in the storage device 113 to the main memory 112, and executes them in a predetermined order to perform various kinds of calculations. The main memory 112 is typically a volatile storage device such as a DRAM (Dynamic Random Access Memory).

Also, the program according to the example embodiments are provided in the state of being stored in a computer-readable recording medium 120. Note that the program according to the first and second example embodiments and the first and second working examples may be distributed on the Internet that is connected via the communication interface 117.

Specific examples of the storage device 113 include a hard disk drive, and a semiconductor storage device such as a flash memory. The input interface 114 mediates data transmission between the CPU 111 and the input device 118 such as a keyboard or a mouse. The display controller 115 is connected to a display device 119, and controls the display of the display device 119.

The data reader/writer 116 mediates data transmission between the CPU 111 and the recording medium 120, and reads out the program from the recording medium 120 and writes the results of processing performed in the computer 110 to the recording medium 120. The communication interface 117 mediates data transmission between the CPU 111 and another computer.

Specific examples of the recording medium 120 include general-purpose semiconductor storage devices such as a CF (Compact Flash (registered trademark)) and a SD (Secure Digital), a magnetic recording medium such as a flexible disk, and an optical recording medium such as a CD-ROM (Compact Disk Read Only Memory).

The information processing apparatus 10 according to the example embodiment can also be achieved using hardware corresponding to the components, instead of a computer in which a program is installed. Furthermore, a part of the information processing apparatus 10 may be realized by a program and the remaining part may be realized by hardware. In the example embodiments, the computer is not limited to the computer shown in FIG. 11.

### SUPPLEMENTARY NOTE

Furthermore, the following supplementary notes are disclosed regarding the example embodiment described above. Some portion or all of the example embodiments described above can be realized according to (supplementary note 1) to (supplementary note 15) described below, but the below description does not limit the present invention.

### Supplementary Note 1

An information processing apparatus, comprising:
a setting unit for setting parameter sets of a traffic-flow theoretical model to be used in traffic-flow simulation that applies the traffic-flow theoretical model,
a simulation unit for running the traffic-flow simulation for each of the parameter sets, and
a determining unit for selecting traffic-flow simulation data, similar to traffic-flow measurement data actually measured, from the traffic-flow simulation data as a result of the traffic-flow simulation, and determining a parameter set corresponding to the selected similar traffic-flow simulation data for a parameter set to be used in traffic-flow prediction.

### Supplementary Note 2

The information processing apparatus according to Supplementary Note 1, wherein
the simulation unit further performs the traffic-flow simulation for a predetermined period of time after current time to predict traffic-flow with use of the parameter set to be used in the traffic-flow prediction.

### Supplementary Note 3

The information processing apparatus according to Supplementary Note 1, wherein
the traffic-flow theoretical model is the S-NFS (Stochastic Nishinari-Fukui-Schadschneider) model.

### Supplementary Note 4

The information processing apparatus according to Supplementary Note 3, wherein
if the S-NFS model is used as the traffic-flow theoretical model, the parameter set is a maximum velocity within a bottleneck, a random brake probability, a slow-to-start probability, and an anticipation probability.

### Supplementary Note 5

The information processing apparatus according to Supplementary Note 1, wherein
the determining unit calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.

### Supplementary Note 6

An information processing method, causing an information processing apparatus
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to traffic-flow measurement data actually measured, from the traffic-flow simulation data as a result of the traffic-flow simulation, and
determining a parameter set, corresponding to the selected similar traffic-flow simulation data, for a parameter set to be used in traffic-flow prediction.

### Supplementary Note 7

The information processing method according to Supplementary Note 6, further causing the information processing apparatus
to perform the traffic-flow simulation for a predetermined period of time after current time to predict traffic-flow with use of the parameter set to be used in the traffic-flow prediction.

### Supplementary Note 8

The information processing method according to Supplementary Note 6, wherein
the traffic-flow theoretical model is the S-NFS (Stochastic Nishinari-Fukui-Schadschneider) model.

### Supplementary Note 9

The information processing method according to Supplementary Note 8, wherein,
if the S-NFS model is used as the traffic-flow theoretical model, the parameter set is a maximum velocity within a bottleneck, a random brake probability, a slow-to-start probability, and an anticipation probability.

### Supplementary Note 10

The information processing method according to Supplementary Note 6, wherein
in the determining, calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.

### Supplementary Note 11

A computer readable recording medium that includes a program recorded thereon, the program including instructions that causes a computer to carry out:
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to traffic-flow measurement data actually measured, from the traffic-flow simulation data as a result of the traffic-flow simulation, and
determining a parameter set, corresponding to the selected similar traffic-flow simulation data, for a parameter set to be used in traffic-flow prediction.

### Supplementary Note 12

The computer readable recording medium that includes the program according to Supplementary Note 11 recorded thereon,
the program including instructions that causes the computer to carry out:
performing the traffic-flow simulation for a predetermined period of time after current time to predict traffic-flow with use of the parameter set to be used in the traffic-flow prediction.

### Supplementary Note 13

The computer readable recording medium according to Supplementary Note 11, wherein
the traffic-flow theoretical model is the S-NFS (Stochastic Nishinari-Fukui-Schadschneider) model.

### Supplementary Note 14

The computer readable recording medium according to Supplementary Note 13, wherein
if the S-NFS model is used as the traffic-flow theoretical model, the parameter set is a maximum velocity within a bottleneck, a random brake probability, a slow-to-start probability, and an anticipation probability.

### Supplementary Note 15

The computer readable recording medium according to Supplementary Note 11, wherein
in the determining, calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.

Although the present invention of this application has been described with reference to exemplary embodiments, the present invention of this application is not limited to the above exemplary embodiments. Within the scope of the present invention of this application, various changes that can be understood by those skilled in the art can be made to the configuration and details of the present invention of this application.

### INDUSTRIAL APPLICABILITY

According to the disclosure as described above, traffic-flow prediction can be performed using the parameter set of the traffic-flow theoretical model with high accuracy that can reproduce a traffic condition similar to a current traffic condition. Further, the present invention is useful in a field where traffic-flow prediction is required.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each embodiment can be appropriately combined with other embodiments.

1. An information processing apparatus, comprising:
at least one memory storing instructions; and
at least one processor configured to execute the instructions to:
set parameter sets of a traffic-flow theoretical model to be used in traffic-flow simulation that applies the traffic-flow theoretical model,
run the traffic-flow simulation for each of the parameter sets, and
select traffic-flow simulation data, similar to traffic-flow measurement data actually measured, from the traffic-flow simulation data as a result of the traffic-flow simulation, and determine a parameter set corresponding to the selected similar traffic-flow simulation data for a parameter set to be used in traffic-flow prediction.

2. The information processing apparatus according to claim 1, wherein
the one or more processors further:
further performs the traffic-flow simulation for a predetermined period of time after current time to predict traffic-flow with use of the parameter set to be used in the traffic-flow prediction.

3. The information processing apparatus according to claim 1, wherein
the traffic-flow theoretical model is the S-NFS (Stochastic Nishinari-Fukui-Schadschneider) model.

4. The information processing apparatus according to claim 3, wherein
if the S-NFS model is used as the traffic-flow theoretical model, the parameter set is a maximum velocity within a bottleneck, a random brake probability, a slow-to-start probability, and an anticipation probability.

5. The information processing apparatus according to claim 1, wherein
the one or more processors further:
calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.

6. An information processing method, causing an information processing apparatus
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to traffic-flow measurement data actually measured, from the traffic-flow simulation data as a result of the traffic-flow simulation, and
determining a parameter set, corresponding to the selected similar traffic-flow simulation data, for a parameter set to be used in traffic-flow prediction.

7. The information processing method according to claim 6, further causing the information processing apparatus
to perform the traffic-flow simulation for a predetermined period of time after current time to predict traffic-flow with use of the parameter set to be used in the traffic-flow prediction.

8. The information processing method according to claim 6, wherein
the traffic-flow theoretical model is the S-NFS (Stochastic Nishinari-Fukui-Schadschneider) model.

9. The information processing method according to claim 8, wherein,
if the S-NFS model is used as the traffic-flow theoretical model, the parameter set is a maximum velocity within a bottleneck, a random brake probability, a slow-to-start probability, and an anticipation probability.

10. The information processing method according to claim 6, wherein
in the determining, calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.

11. A non-transitory computer readable recording medium that includes a program recorded thereon, the program including instructions that causes a computer to carry out:
setting parameter sets of a traffic-flow theoretical model to be used in traffic-flow simulation that applies the traffic-flow theoretical model,
running the traffic-flow simulation for each of the parameter sets,
selecting traffic-flow simulation data, similar to traffic-flow measurement data actually measured, from the traffic-flow simulation data as a result of the traffic-flow simulation, and
determining a parameter set, corresponding to the selected similar traffic-flow simulation data, for a parameter set to be used in traffic-flow prediction.

12. The non-transitory computer readable recording medium that includes the program according to claim 11 recorded thereon,
the program including instructions that causes the computer to carry out:
performing the traffic-flow simulation for a predetermined period of time after current time to predict traffic-flow with use of the parameter set to be used in the traffic-flow prediction.

13. The non-transitory computer readable recording medium according to claim 11, wherein
the traffic-flow theoretical model is the S-NFS (Stochastic Nishinari-Fukui-Schadschneider) model.

14. The non-transitory computer readable recording medium according to claim 13, wherein
if the S-NFS model is used as the traffic-flow theoretical model, the parameter set is a maximum velocity within a bottleneck, a random brake probability, a slow-to-start probability, and an anticipation probability.

15. The non-transitory computer readable recording medium according to claim 11, wherein
in the determining, calculates a posterior probability distribution, a maximum a posteriori, or an expectation of the posterior probability distribution, or all of them for each parameter set in accordance with similarity between the traffic-flow measurement data and the traffic-flow simulation data, and, based on one or more of these, determines the parameter set to be used in the traffic-flow prediction.
